(19) United States
(12) Patent Application Publication
(10) Pub. No.: US 2015/0263057 A1
(43) Pub. Date: Sep. 17, 2015

(54) METHOD FOR MANUFACTURING METAL WIRING AND METHOD FOR MANUFACTURING SOLID STATE IMAGING DEVICE

(71) Applicant: Kabushiki Kaisha Toshiba, Minato-ku (JP)

(72) Inventors: Masaharu OGASAWARA, Kitakami (JP); Masaki Kikuchi, Kitakami (JP); Takuto Inoue, Kitakami (JP)

(73) Assignee: Kabushiki Kaisha Toshiba, Minato-ku (JP)

(21) Appl. No.: 14/621,835

(22) Filed: Feb. 13, 2015

(30) Foreign Application Priority Data
Mar. 14, 2014 (JP) 2014-052000

(51) Int. Cl. H01L 27/146; H01L 21/768; H01L 21/3213; H01L 21/311; H01L 21/3205; H01L 21/02

(52) U.S. Cl. CPC H01L 27/14636; H01L 27/14689; H01L 27/14643; H01L 21/32051; H01L 21/0214; H01L 21/32135; H01L 27/14685; H01L 27/1462; H01L 21/31116; H01L 21/768; H01L 21/32139; H01L 27/14612

(57) ABSTRACT

Certain embodiments provide a method for forming the metal wiring including a process for forming a metal layer and an organic film on a semiconductor substrate in this order, a process for forming a resist pattern including carbon on a surface of the organic film, a process for etching the organic film for exposing from between the resist pattern by using fluorine-based first gas which does not include oxygen, a process for forming a first sidewall film on a sidewall of the resist pattern during the etching process for using the first gas, and a process for etching the metal layer for exposing from between the resist pattern having the first sidewall film formed thereon.

### CROSS REFERENCE TO RELATED APPLICATIONS

This application is based upon and claims the benefit of priority from the prior Japanese Patent Application No.2014-052000 filed in Japan on Mar. 14, 2014; the entire contents of which are incorporated herein by reference.

### FIELD

Embodiments described herein relate generally to a method for forming metal wiring and a method for manufacturing a solid state imaging device.

### BACKGROUND

For example, metal wiring including metal, for example, aluminum is provided in various semiconductor devices including a CMOS transistor, a solid state imaging device, and the like. The metal wiring is generally manufactured as follows.

First, a metal layer, an organic antireflection film, and a resist layer are evenly formed on a semiconductor substrate via an insulating film. Next, a resist pattern is formed on the organic antireflection film by exposing and developing the resist layer. Next, the organic antireflection film for exposing from the formed resist pattern is etched by using, for example, fluorine-based etching gas including oxygen. Subsequently, the metal layer is etched by using, for example, chlorine-based etching gas. Accordingly, the resist pattern is transferred to the metal layer, and the metal wiring is formed.

As various semiconductor devices including the metal wiring formed in this way have been miniaturized in recent years, a wiring width of the metal wiring and a distance between the metal wirings become short. An interval of the resist pattern tends to be wider as the film thickness of the resist layer is thicker. Therefore, it is necessary to reduce the film thickness of the resist layer as the semiconductor device is miniaturized. As a result, there is a problem in that the resist pattern disappears by the etching before the etching on the metal layer is finished. As a result, the deterioration of a shape, such as a crack, is generated in a part of the metal wiring to be formed, and it becomes difficult to form metal wiring with excellent reliability. Accordingly, it becomes difficult to manufacture a semiconductor device with excellent reliability.

### BRIEF DESCRIPTION OF THE DRAWINGS

FIG. 1 is a partial cross sectional view for schematically illustrating a semiconductor device having metal wiring formed by a method for forming the metal wiring according to an embodiment;

FIG. 2 is a cross sectional view corresponding to FIG. 1 to describe a method for manufacturing a semiconductor device including the method for forming the metal wiring according to the embodiment;

FIG. 3 is a cross sectional view corresponding to FIG. 1 to describe the method for manufacturing a semiconductor device including the method for forming the metal wiring according to the embodiment;

FIG. 4 is a cross sectional view corresponding to FIG. 1 to describe the method for manufacturing a semiconductor device including the method for forming the metal wiring according to the embodiment;

FIG. 5 is a cross sectional view corresponding to FIG. 1 to describe the method for manufacturing a semiconductor device including the method for forming the metal wiring according to the embodiment;

FIG. 6 is a cross sectional view corresponding to FIG. 1 to describe the method for manufacturing a semiconductor device including the method for forming the metal wiring according to the embodiment;

FIG. 7 is a cross sectional view corresponding to FIG. 1 to describe the method for manufacturing a semiconductor device including the method for forming the metal wiring according to the embodiment;

FIG. 8 is a cross sectional view corresponding to FIG. 1 to describe the method for manufacturing a semiconductor device including the method for forming the metal wiring according to the embodiment; and

FIG. 9 is a partial cross sectional view for schematically illustrating a main part of a solid state imaging device having metal wiring formed by the method for forming the metal wiring according to the embodiment.

### DESCRIPTION OF THE EMBODIMENTS

Certain embodiments provide a method for forming the metal wiring including a process for forming a metal layer and an organic film on a semiconductor substrate in this order, a process for forming a resist pattern including carbon on a surface of the organic film, a process for etching the organic film for exposing from between the resist pattern by using fluorine-based first gas which does not include oxygen, a process for forming a first sidewall film on a sidewall of the resist pattern during the etching process for using the first gas, and a process for etching the metal layer for exposing from between the resist pattern having the first sidewall film formed thereon.

Certain embodiments provide a method for manufacturing a solid state imaging device including a process for forming a pixel unit by forming a photodiode layer, a charge storage layer, and a floating diffusion layer on a surface of a semiconductor substrate and forming a gate electrode on the semiconductor substrate, a process for forming an insulating film on the surface of the semiconductor substrate having the pixel unit formed thereon, a process for forming a metal layer and an organic antireflection film on a surface of the insulating film in this order, a process for forming a resist pattern including carbon on a surface of the organic antireflection film, a process for etching the organic antireflection film for exposing from between the resist pattern by using fluorine-based first gas which does not include oxygen, a process for forming a first sidewall film on a sidewall of the resist pattern during the etching process for using the first gas, and a process for forming metal wiring by etching the metal layer for exposing from between the resist pattern having the first sidewall film formed thereon.

A method for forming metal wiring and a method for manufacturing a solid state imaging device according to an embodiment will be described in detail below.

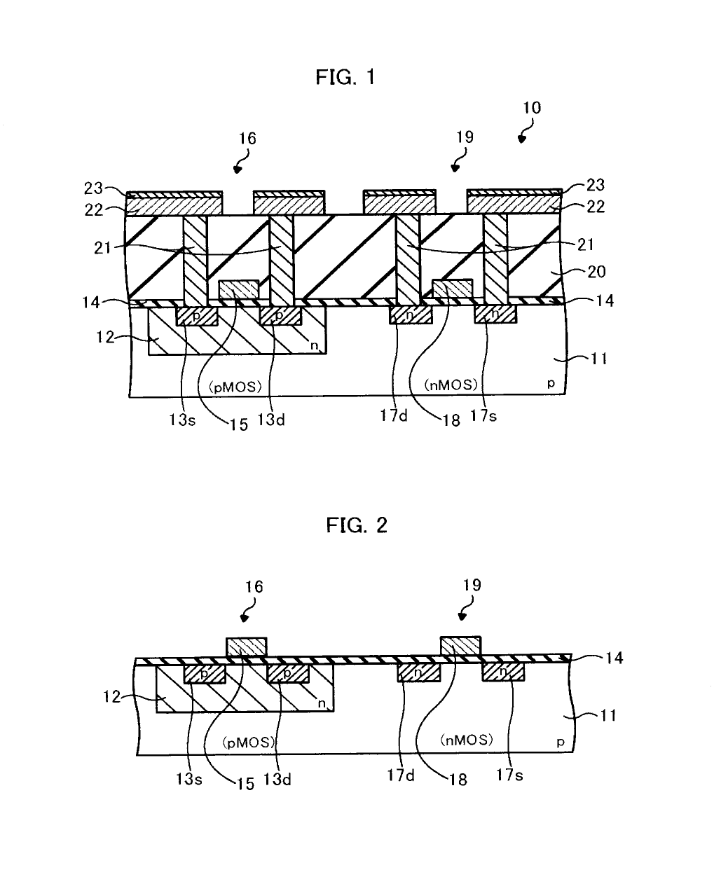

FIG. 1 is a partial cross sectional view for schematically illustrating an exemplary semiconductor device having the metal wiring formed by the method for forming the metal wiring according to the embodiment. The semiconductor device illustrated in FIG. 1 is a CMOS transistor. In a semiconductor device 10 illustrated in FIG. 1, a channel layer 12 which is an n−type impurity layer is provided on a part of a surface of a p−type semiconductor substrate 11 (or a p−type well 11 provided on the semiconductor substrate) formed of, for example, silicon. A drain 13d and a source 13s which are the p−type impurity layers are provided on a surface of the channel layer 12. A gate electrode 15 is provided on the surface of the channel layer 12 between the drain 13d and the source 13s via an oxide film 14. The oxide film 14 is, for example, a silicon oxide film. In this way, a pMOS transistor 16 is formed.

Also, on the surface of the semiconductor substrate 11, a drain 17d and a source 17s which are n−type impurity layers are provided near the pMOS transistor 16. A gate electrode 18 is provided on the surface of the semiconductor substrate 11 between the drain 17d and the source 17s via the oxide film 14. In this way, an nMOS transistor 19 is formed.

An insulating film 20 is provided on the surface of the semiconductor substrate 11 on which various impurity layers and the like are formed in this way via the oxide film 14 so as to cover the gate electrodes 15 and 18. The insulating film 20 is formed of, for example, SiO₂. In the insulating film 20, a plurality of through electrodes 21 is provided. The through electrodes 21 penetrate the insulating film 20 and are respectively connected to the drain 13d and the source 13s of the pMOS transistor 16 and the drain 17d and the source 17s of the nMOS transistor 19.

Metal wiring 22 is formed on the surface of the insulating film 20 so as to be connected to the respective upper ends of the plurality of through electrodes 21. The metal wiring 22 is formed of, for example, aluminum. A barrier metal may be provided on the surface of the metal wiring 22. The barrier metal is formed of, for example, TiN.

An organic antireflection film 23 is formed on the surface of the metal wiring 22. The organic antireflection film 23 is an organic film which is formed of, for example, silicon oxynitride (SiON). The organic antireflection film 23 is provided in order to supplement the insufficient thickness of the resist layer in a case where the resist pattern 24 necessary for forming the metal wiring 22 is formed. The organic antireflection film 23 also has a purpose to prevent the deterioration of the accuracy of the size of the resist pattern 24 due to the diffuse reflection of the exposure light when the resist layer is exposed.

The method for manufacturing the semiconductor device including the method for forming the metal wiring 22 which is formed in the semiconductor device 10 illustrated in FIG. 1 will be described in detail below with reference to FIGS. 2 to 8. FIGS. 2 to 8 are cross sectional views corresponding to FIG. 1 to describe the method for manufacturing the semiconductor device including the method for forming the metal wiring 22 according to the embodiment.

First, as illustrated in FIG. 2, the pMOS transistor 16 and the nMOS transistor 19 are formed on the semiconductor substrate (or the p−type well provided on the semiconductor substrate) 11 which is, for example, a silicon substrate. It is preferable that the pMOS transistor 16 and the nMOS transistor 19 be formed by using a general forming method. For example, the pMOS transistor 16 and the nMOS transistor 19 are formed as follows.

First, on the surface of the p−type semiconductor substrate 11, which is formed of silicon, having the oxide film 14 provided on its surface, the n−type channel layer 12 is formed by ion implantation. Next, the gate electrode 15 is formed on the channel layer 12 via the oxide film 14, and at the same time, the gate electrode 18 is formed on the semiconductor substrate 11 except for the channel layer 12 via the oxide film 14. The gate electrodes 15 and 18 are formed by, for example, patterning. After that, the p−type drain 13d and the p−type source 13s are formed on the surface of the channel layer 12, and the n−type drain 17d and the n−type source 17s are formed on the surface of the semiconductor substrate 11 except for the channel layer 12. The drains 13d and 17d and the sources 13s and 17s are formed by the ion implantation, for example. In this way, the pMOS transistor 16 and the nMOS transistor 19 are formed.

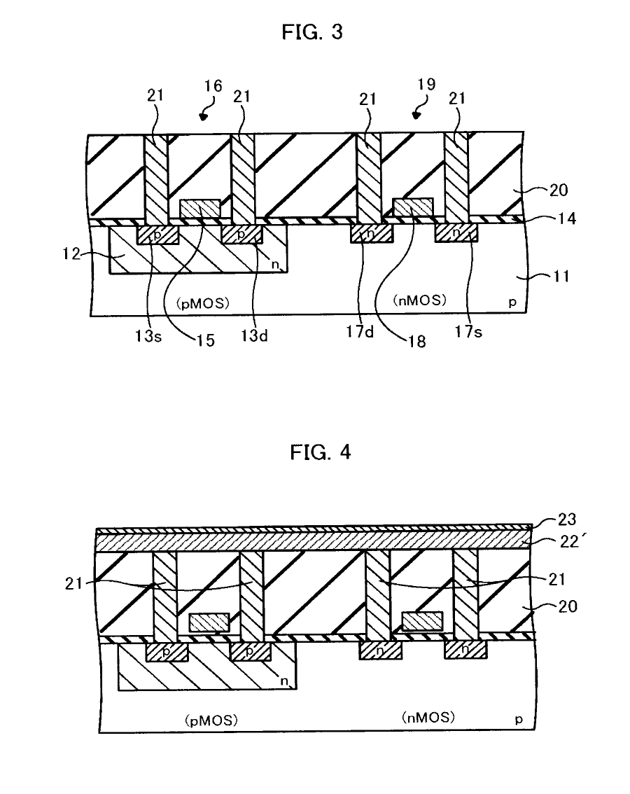

Next, as illustrated in FIG. 3, the insulating film 20 is formed on the surface of the semiconductor substrate 11 having the pMOS transistor 16 and the nMOS transistor 19 formed thereon via the oxide film 14. The insulating film 20 is formed of, for example, SiO₂. Subsequently, the plurality of through electrodes 21 is formed so as to penetrate the insulating film 20 and the oxide film 14 and respectively contact with the drains 13d and 17d and the sources 13s and 17s.

Next, as illustrated in FIG. 4, the metal layer 22′ and the organic antireflection film 23 are laminated on the surface of the insulating film 20 in this order so as to contact with the upper ends of the plurality of through electrodes 21. The metal layer 22′ becomes the metal wiring 22 (FIG. 1) later, and the organic antireflection film 23 is the organic film. In the present embodiment, the metal layer 22′ is, for example, an aluminum (Al) layer and the organic antireflection film 23 is, for example, a silicon oxynitride (SiON) film.

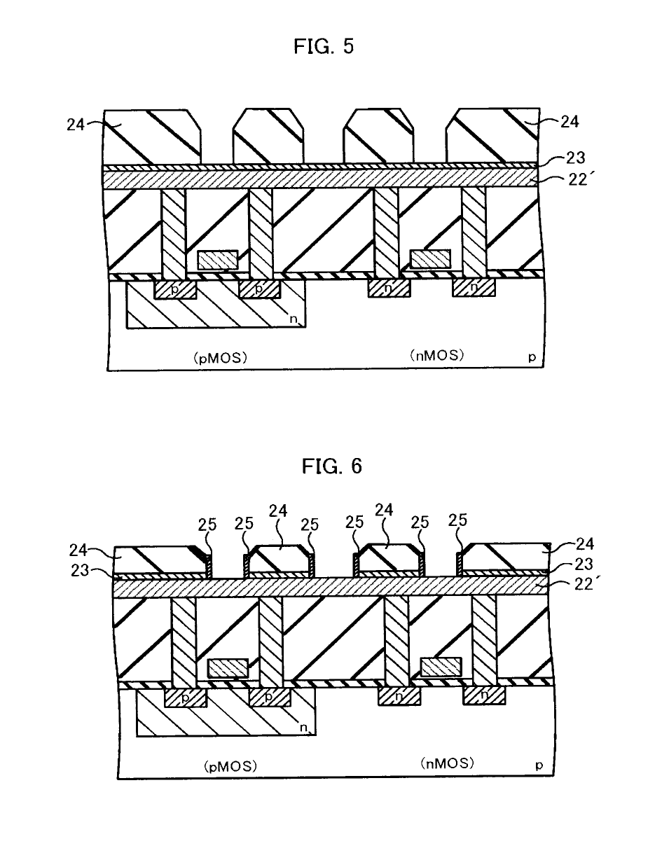

After the metal layer 22′ and the organic antireflection film 23 have been formed, the resist layer is formed on the surface of the organic antireflection film 23 as illustrated in FIG. 5. Then, the resist pattern 24 is formed by exposing and developing the resist layer. The resist pattern 24 is formed of a photosensitive material including at least carbon (C). Since the resist pattern 24 is formed on the organic antireflection film 23, the diffuse reflection of the exposure light at the time of forming the resist pattern 24 is prevented. Accordingly, the resist pattern 24 is accurately formed.

Next, as illustrated in FIG. 6, for example, by using a capacitively coupled plasma (CCP) apparatus or an inductively coupled plasma (ICP) apparatus, the organic antireflection film 23 for exposing from between the resist pattern 24 is etched by using fluorine-based etching gas (referred to as “first gas” below) which does not include oxygen (O₂). The first gas is mixed gas having, for example, C₄F₈, CO, and Ar as main components. When the etching is performed by using the first gas, the organic antireflection film 23 disappears by the etching. At the same time, a first sidewall protective film 25 is formed on the sidewall of the resist pattern 24. The first sidewall protective film 25 is a first sidewall film formed of a reaction product of the first gas, the resist pattern 24, and the organic antireflection film 23. On the sidewall of the resist pattern 24, the first sidewall protective film 25 is formed to be thick on a surface substantially perpendicular to the insulating film 20 and formed to be thin on an inclined surface. The first sidewall protective film 25 is formed of, for example, C—F, C—O, C—N, and the like.

Even when the organic antireflection film 23 is etched as conventional by using the fluorine-based etching gas (for example, C₄F₈/CO/Ar/O₂) including oxygen (O₂), the first sidewall protective film 25 is formed on the sidewall of the resist pattern 24 as described above. However, the film thickness of the formed first sidewall protective film 25 is not enough. Therefore, in a subsequent etching process of the metal layer 22′, the resist pattern 24 disappears before the etching of the metal layer 22′ ends and the deterioration of a shape, such as a crack, is generated in a part of the metal wiring 22 to be formed. As a result, it is difficult to form the metal wiring 22 with excellent reliability.

That is, in the present embodiment, a process illustrated in FIG. 6 is a process for promoting the generation of the first sidewall protective film 25 by using the first gas in which oxygen (O₂) is removed from the etching gas used in the conventional etching process of the organic antireflection film 23.

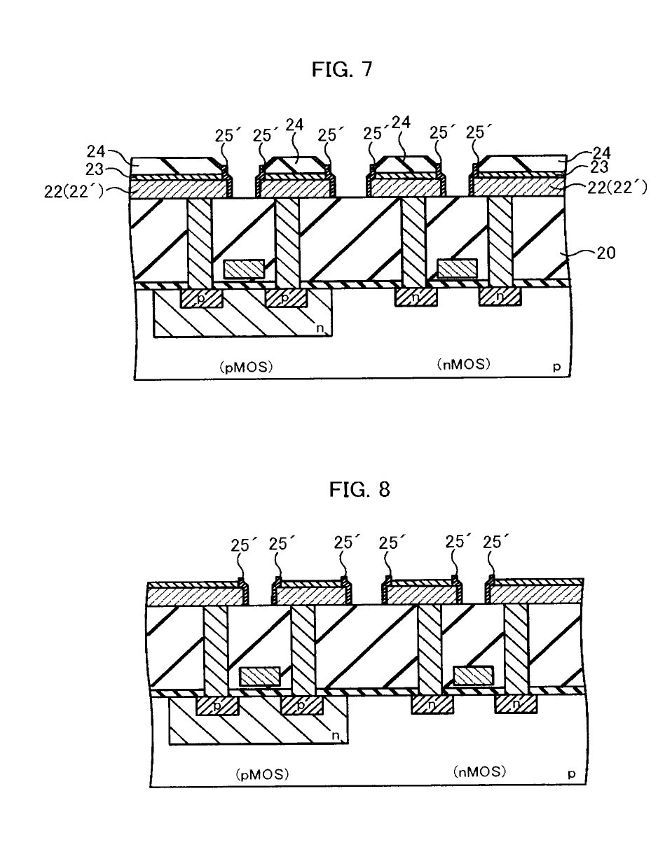

Next, as illustrated in FIG. 7, the metal layer 22′ for exposing from between the resist pattern 24 having the first sidewall protective film 25 formed thereon is etched, and the metal wiring 22 is formed on the insulating film 20. In the present embodiment, the metal layer 22′ is etched by using chlorine-based etching gas (referred to as “second gas” below). The second gas is mixed gas having, for example, Cl₂, BCl₃, and CH₄ as main components. When the barrier metal formed of, for example, TiN has been provided on the surface of the metal layer 22′, the barrier metal is etched by using chlorine-based etching gas (referred to as “third gas” below). The third gas is mixed gas having, for example, Cl₂, Ar, and CHF₃ as main components.

The resist pattern 24 is etched in this etching process. However, since the first sidewall protective film 25 is formed on the sidewall of the resist pattern 24, the resist pattern 24 is protected from the second gas for etching the metal layer 22′. Then, the disappearance of the resist pattern 24 caused by the etching is prevented. As a result, at the time when the etching of the metal layer 22′ ends, a resist residual film of the resist pattern 24 is ensured. That is, at the time when the etching of the metal layer 22′ ends, the resist pattern 24 can be maintained. Therefore, the metal wiring 22 having a good shape and without a defect such as the crack is formed.

Also, in this process, a second sidewall protective film 25′ is accumulated on the sidewalls of the metal wiring 22, the organic antireflection film 23, and the resist pattern 24. The second sidewall protective film 25′ is a second sidewall film formed of a reaction product of the second gas, the resist pattern 24, and the metal layer 22′. Among the sidewalls of the metal wiring 22, the organic antireflection film 23, and the resist pattern 24, the second sidewall protective film 25′ is also formed to be thick on the surface substantially perpendicular to the insulating film 20 and formed to be thin on an inclined surface of the resist pattern 24. The second sidewall protective film 25′ is formed of, for example, Al—O, Al—Cl, Ti—Cl, C—O, and the like. The second sidewall protective film 25′ includes the first sidewall protective film 25 which is maintained at the time when the process of FIG. 6 has ended.

Whereas, when the very thin sidewall protective film 25 having the film thickness which is equal to or thinner than the necessary thickness is formed on the sidewall of the resist pattern 24, the etching of the resist pattern 24 is progressed without being prevented in the etching process of the metal layer 22′. Accordingly, the resist pattern 24 may disappear before the etching of the metal layer 22′ ends. As a result, the defect such as the crack is generated in the metal wiring 22 to be formed.

Next, as illustrated in FIG. 8, the resist pattern 24 for maintaining is removed, for example, by ashing. At this time, the sidewall protective film 25′ formed to be thin on the inclined surface of the resist pattern 24 is concurrently removed. Subsequently, the second sidewall protective film 25′ for maintaining is removed, for example, by wet etching using a fluorine-containing water-soluble inorganic component and the like.

According to the process above, the semiconductor device 10 including the metal wiring 22 as illustrated in FIG. 1 is manufactured.

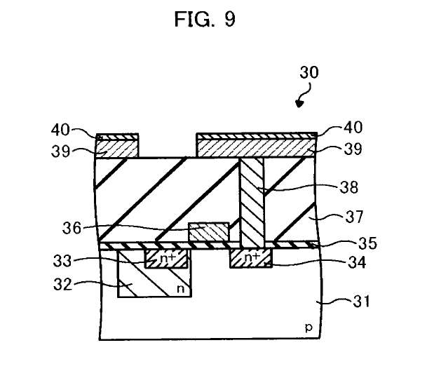

The above-mentioned method for forming the metal wiring 22 can be applied to the method for manufacturing the solid state imaging device. FIG. 9 is a partial cross sectional view for schematically illustrating a main part of a solid state imaging device having metal wiring formed by the method for forming the metal wiring according to the embodiment.

A solid state imaging device 30 illustrated in FIG. 9 is a so-called CMOS sensor. One of pixel units of the solid state imaging device 30 which is the CMOS sensor is enlarged and illustrated in FIG. 9. The actual solid state imaging device 30 includes a plurality of pixel units illustrated in FIG. 9 and is configured by two-dimensionally arranging the plurality of pixel units.

As illustrated in FIG. 9, a photodiode layer 32 which is an n−type impurity layer is provided on a part of a surface of a p−type semiconductor substrate (or a p−type well provided on a semiconductor substrate) 31 in the solid state imaging device 30. The p−type semiconductor substrate 31 is formed of, for example, silicon. In addition, a charge storage layer 33 which is an n+type impurity layer is provided on a part of the surface of the photodiode layer 32. Also, the floating diffusion layer 34 which is an n+type impurity layer is provided at a position apart from the photodiode layer 32 on the surface of the semiconductor substrate 31.

A transfer gate electrode 36 is provided on the surface of the semiconductor substrate 31 between the photodiode layer 32 and the floating diffusion layer 34 via an oxide film 35 such as a silicon oxide film.

An insulating film 37 is provided on the surface of the semiconductor substrate 31 on which various impurity layers and the like are formed in this way via the oxide film 35 so as to cover the transfer gate electrode 36. The insulating film 37 is formed of, for example, SiO₂. In the insulating film 37, a through electrode 38 for penetrating the insulating film 37 and being connected to the floating diffusion layer 34 is provided.

Metal wiring 39 is formed on the surface of the insulating film 37 so as to be connected to an upper end of the through electrode 38. The metal wiring 39 is formed of, for example, aluminum. The metal wiring 39 is provided not to cover the place just above the photodiode layer 32. A barrier metal may be provided on the surface of the metal wiring 39. The barrier metal is formed of, for example, TiN.

An organic antireflection film 40 is formed on the surface of the metal wiring 39. The organic antireflection film 40 is an organic film which is formed of, for example, silicon oxynitride (SiON).

A color filter layer, a microlens, and the like which are not illustrated are provided above the metal wiring 39.

When the photodiode layer 32 receives the light and generates charges in the pixel unit of the solid state imaging device 30, the charges are collected in the charge storage layer 33. The charges moved to the charge storage layer 33 are temporarily accumulated in the charge storage layer 33. However, when a desired voltage is applied to the transfer gate electrode 36, the charges accumulated in the charge storage layer 33 are transferred to the floating diffusion layer 34. When the charges are transferred to the floating diffusion layer 34, a voltage corresponding to the amount of the transferred charges is generated in the floating diffusion layer 34. The generated voltage is output from the pixel unit via the through electrode 38 and the metal wiring 39.

A method for manufacturing the solid state imaging device 30 described above is as follows. First, the pixel unit is formed on the semiconductor substrate (or the p−type well provided on the semiconductor substrate) 31 which is, for example, a silicon substrate. It is preferable that the pixel unit be formed by using a general forming method. For example, the pixel unit is formed as follows.

First, the n−type photodiode layer 32 is formed by the ion implantation on the surface of the p−type semiconductor substrate 31 having the oxide film 35 provided on its surface. The p−type semiconductor substrate 31 is formed of silicon. Next, the transfer gate electrode 36 is formed on the photodiode layer 32 via the oxide film 35, for example, by patterning. After that, the n+type charge storage layer 33 and the n+type floating diffusion layer 34 are formed on the surface of the semiconductor substrate 31 including the photodiode layer 32, for example, by the ion implantation. In this way, the pixel unit is formed.

After the pixel unit has been formed in this way, the insulating film 37, the through electrode 38, the metal wiring 39, and the organic antireflection film 40 are formed according to the method similar to the method illustrated in FIGS. 3 to 8.

In this way, the solid state imaging device 30 including the metal wiring 39 as illustrated in FIG. 9 is manufactured.

As described above, the fluorine-based etching gas (first gas) which does not include oxygen is used as the etching gas at the time when the organic antireflection films 23 and 40 are etched in the method for forming the metal wiring, the method for manufacturing the semiconductor device, and the method for manufacturing the solid state imaging device according to the present embodiment. As a result, when the organic antireflection films 23 and 40 are etched, the formation of the first sidewall protective film 25 on the sidewall of the resist pattern 24 is promoted. Therefore, the disappearance of the resist pattern 24 before the etching of the metal layer 22′ ends is prevented, and the resist residual film of the resist pattern 24 is ensured at the time when the etching of the metal layer 22′ ends. As a result, the metal wirings 22 and 39 having a good shape and without a defect such as the crack can be formed, and the metal wirings 22 and 39 with excellent reliability can be formed. Accordingly, the semiconductor device 10 with excellent reliability can be manufactured. Also, the solid state imaging device 30 with excellent reliability can be manufactured.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for forming metal wiring comprising:
forming a metal layer and an organic film on a semiconductor substrate in this order;
forming a resist pattern including carbon on a surface of the organic film;
etching the organic film for exposing from between the resist pattern by using fluorine-based first gas which does not include oxygen;
forming a first sidewall film on a sidewall of the resist pattern during the etching process for using the first gas; and
etching the metal layer for exposing from between the resist pattern on which the first sidewall film has been formed.

2. The method for forming metal wiring according to claim 1, wherein
the remained resist pattern is removed after the metal layer has been etched.

3. The method for forming metal wiring according to claim 1, wherein
the first sidewall film is formed of a reaction product of the first gas, the resist pattern, and the organic film.

4. The method for forming metal wiring according to claim 3, wherein
the first gas is mixed gas, which does not include the oxygen, having C₄F₈, CO, and Ar as main components.

5. The method for forming metal wiring according to claim 4, wherein
the organic film is a SiON film.

6. The method for forming metal wiring according to claim 1, wherein
a second sidewall film is formed on the sidewall of the resist pattern during the etching process of the metal layer.

7. The method for forming metal wiring according to claim 6, wherein
the remained resist pattern is removed after the metal layer has been etched, and the remained second sidewall film is removed after the resist pattern has been removed.

8. The method for forming metal wiring according to claim 6, wherein
the second sidewall film is formed of a reaction product of second gas used when the metal layer is etched, the resist pattern, and the metal layer.

9. The method for forming metal wiring according to claim 8, wherein
the second gas is mixed gas having Cl₂, BCl₃, and CH₄ as main components.

10. The method for forming metal wiring according to claim 9, wherein
the metal layer is formed of aluminum.

11. A method for manufacturing a solid state imaging device: comprising:
forming a pixel unit, the pixel unit formed by forming a photodiode layer, a charge storage layer, and a floating diffusion layer on a surface of a semiconductor substrate and forming a gate electrode on the semiconductor substrate;
forming an insulating film on the surface of the semiconductor substrate on which the pixel unit has been formed;
forming a metal layer and an organic antireflection film on a surface of the insulating film in this order;
forming a resist pattern including carbon on a surface of the organic antireflection film;
etching the organic antireflection film for exposing from between the resist pattern by using fluorine-based first gas which does not include oxygen;
forming a first sidewall film on a sidewall of the resist pattern during the etching process for using the first gas; and
forming metal wiring by etching the metal layer for exposing from between the resist pattern on which the first sidewall film has been formed.

12. The method for manufacturing a solid state imaging device according to claim 11, wherein
the remained resist pattern is removed after the metal wiring has been formed.

13. The method for manufacturing a solid state imaging device according to claim 11, wherein
the first sidewall film is formed of a reaction product of the first gas, the resist pattern, and the organic antireflection film.

14. The method for manufacturing a solid state imaging device according to claim 13, wherein
the first gas is mixed gas, which does not include the oxygen, having C₄F₈, CO, and Ar as main components.

15. The method for manufacturing a solid state imaging device according to claim 14, wherein
the organic antireflection film is a SiON film.

16. The method for manufacturing a solid state imaging device according to claim 11, wherein
a second sidewall film is formed on a sidewall of the resist pattern during the etching process of the metal layer.

17. The method for manufacturing a solid state imaging device according to claim 16, wherein
the remained resist pattern is removed after the metal layer has been etched, and the remained second sidewall film is removed after the resist pattern has been removed.

18. The method for manufacturing a solid state imaging device according to claim 16, wherein
the second sidewall film is formed of a reaction product of second gas used when the metal layer is etched, the resist pattern, and the metal layer.

19. The method for manufacturing a solid state imaging device according to claim 18, wherein
the second gas is mixed gas having Cl₂, BCl₃, and CH₄ as main components.

20. The method for manufacturing a solid state imaging device according to claim 19, wherein
the metal layer is formed of aluminum.
